(19) United States
(12) Patent Application Publication
(10) Pub. No.: US 2007/0267676 A1
(43) Pub. Date: Nov. 22, 2007

(54) Fin field effect transistor and method for forming the same

(75) Inventors: Keunnam Kim, Suwon-si (KR); Makoto Yoshida, Suwon-si (KR); Donggun Park, Seongnam-si (KR); Wounsuck Yang, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/714,161

(22) Filed: Mar. 6, 2007

(30) Foreign Application Priority Data
May 22, 2006 (KR) 10-2006-0045494

(51) Int. Cl. H01L 21/336; H01L 21/8242; H01L 29/78; H01L 27/108

(52) U.S. Cl. 257/311; 257/332; 438/239; 438/270; 257/E27.084; 257/E21.409; 257/E29.255; 257/E21.646

(57) ABSTRACT

Example embodiments are directed to a method of forming a field effect transistor (FET) and a field effect transistor (FET) including at least one buried gate structure, buried entirely below an upper surface of an active fin and an upper surface of the isolation region.

### PRIORITY STATEMENT

This application claims priority under 35 U.S.C. § 119 to Korean Patent Application No. 10-2006-45494 filed on May 22, 2006, the contents of which are herein incorporated by reference in their entirety for all purposes.

### BACKGROUND

1. Field

Example embodiments relate to field effect transistors (FETs), for example, to FETs and methods for manufacturing FETs

2. Description of the Related Art

As the integration density of integrated circuit field effect transistors continues to increase, the size of the active region and the channel length may continue to decrease. With the reduction in the channel length of the transistor, the influence of the source/drain upon the electric field or potential in the channel region may become considerable. This is called the “short channel effect”.

Further, with scaling down active size of the transistor, the channel width decreases which may increase a threshold voltage. This is called the “narrow width effect”. Various structures have been developed in attempts to improve or maximize device performance, while reducing the sizes of elements formed on a substrate.

For example, fin field effect transistors (FinFETs) have been proposed. FinFETs are currently the main transistor structure for memory devices. However, conventional FinFETs transistor may also have problems, for example, a misaligned gate node and a complicated manufacturing process.

FIG. 1 illustrates a FinFET or recessed gate structure in accordance with the conventional art. A conventional FinFET may include a gate insulation layer 10, a gate electrode 12, and/or a gate hard mask 14. As illustrated in FIG. 1, the FinFET structure may be misaligned during photo processing.

Additionally, two photo processing steps are necessary to form the structure of FIG. 1. As a result, device performance may be poorer and/or processing costs may be higher.

### SUMMARY

Example embodiments provide a buried gate node structure. A buried gate node structure has no misaligned gate node and a simpler manufacturing process.

Example embodiments are directed to a field effect transistor (FET), including an active fin formed from a substrate, the active fin surrounded by an isolation region and including a source and a drain, and a recessed region in a center area between the source and the drain, and at least one buried gate structure, including a buried gate electrode and a buried gate mask, the at least one buried gate structure substantially perpendicular to the active fin and overlapping the active fin in the recessed region in the center area between the source and the drain, the at least one buried gate structure buried entirely below an upper surface of the active fin and an upper surface of the isolation region.

In example embodiments, the upper surface of the active fin is substantially planar with the upper surface of the isolation region.

In example embodiments, an upper surface of the active fin is substantially planar with an upper surface of the isolation region and a first portion of the upper surface of the isolation region is substantially planar with an upper surface of the active fin and a second portion of the upper surface of the isolation region adjacent to the active fin is lower than the upper surface of the active fin.

In example embodiments, the at least one buried gate structure may further include a buried gate spacer on sidewalls of the buried gate electrode, wherein the buried gate spacer is buried entirely below the upper surface of the active fin and the upper surface of the isolation region.

In example embodiments, the buried gate spacer is as wide as the active fin.

In example embodiments, the buried gate structure in the isolation region has a first depth and the buried gate structure in the recessed portion has a second depth, the first depth greater than the second depth.

In example embodiments, the FinFET may further include a gate insulation layer on the active fin.

In example embodiments, the FinFET may further include an oxide layer between the substrate and the active fin and the isolation region and a nitride layer between the oxide layer and the isolation region.

In example embodiments, a bottom surface of the recessed region has a semicircular shape.

In example embodiments, the recessed region increases a surface area overlap between the at least one buried gate structure and the active fin.

In example embodiments, a DRAM may include a FinFET, a bit line contact, connecting the source to a bit line, and a storage node contact, connecting the drain to a storage node.

In example embodiments, a DRAM may include a FinFET, a first contact plug, contacting the source, a second contact plug, contacting the drain, a bit line contact, connecting the first contact plug to a bit line, and a storage node contact, connecting the second contact plug to a storage node.

Example embodiments are directed to a method of forming a field effect transistor (FET) including forming an active fin, including a source area and drain area, from a substrate and an isolation region surrounding the active fin, forming a recessed region in a center area of the active fin, and forming a buried gate structure, including a buried gate electrode and a buried gate mask, substantially perpendicular to the active fin and overlapping the active fin in the recessed region in the center area between the source and the drain and buried entirely below an upper surface of the active fin and an upper surface of the isolation region.

In example embodiments, the upper surface of the active fin is substantially planar with the upper surface of the isolation region and an upper surface of the buried gate mask.

In example embodiments, an upper surface of the active fin is substantially planar with an upper surface of the isolation region and a first portion of the upper surface of the isolation region is substantially planar with an upper surface of the active fin and a second portion of the upper surface of the isolation region adjacent to the active fin is lower than the upper surface of the active fin.

In example embodiments, the active fin and the isolation region are formed by shallow trench isolation (STI).

In example embodiments, forming the active fin may further include forming a pad oxide on the substrate, forming a hard mask layer on the pad oxide by chemical vapor deposition (CVD), and forming an isolation layer in the isolation region.

In example embodiments, forming the recessed region in the center area of the active fin may further include forming a trench in the hard mask layer and the isolation layer, where a depth of trench in the hard mask layer is shallower than a depth of the trench in the isolation layer, removing a top portion of the hard mask layer, and forming the recessed region in the active fin, where a depth of the recessed region in the active fin is shallower than a depth of the trench in the isolation layer

In example embodiments, forming the buried gate structure may further include forming a gate insulation layer on the active fin and in the recessed region of the active fin, forming a gate electrode layer on the gate insulation layer on the active fin and in the recessed region of the active fin, removing an entire portion of the gate electrode layer on the active fin and a top portion of the gate electrode layer in the recessed region of the active fin and a remaining portion of the gate electrode layer such that the remaining buried gate electrode is entirely below the upper surface of the active fin, and forming a gate mask in the recessed region of the active fin.

In example embodiments, the gate insulation layer may include at least one of an oxide layer, a nitride layer, and a metal oxide layer.

In example embodiments, forming the buried gate structure may further include forming a buried gate spacer on sidewalls of the buried gate electrode, wherein the buried gate spacer is entirely below the upper surface of the active fin and the upper surface of the isolation region.

In example embodiments, the method may further include forming a source and a drain in the source area and drain area, respectively, by ion implantation.

In example embodiments, the method may further include forming a bit line contact, connecting the source to a bit line and forming a storage node contact, connecting the drain to a storage node.

In example embodiments, the method may further include forming a first contact plug, contacting the source, forming a second contact plug, contacting the drain, forming a bit line contact, connecting the first contact plug to a bit line, and forming a storage node contact, connecting the second contact plug to a storage node.

Example embodiments are directed to a method of forming a field effect transistor (FET) including forming an active fin and isolation layer on a substrate by shallow trench isolation, forming a trench in a center area of the active fin and the isolation layer, where a depth of the trench in the active fin is shallower than a depth of the trench in the isolation layer, forming a recessed region in the center area of the active fin, depositing a gate insulation layer on an upper surface of the active fin and in the recessed region, forming a gate structure buried entirely in the recessed region, and forming a source and drain, at an upper portion of the active fin, elevated with respect to the gate structure.

In example embodiments, forming the gate structure may include forming a gate electrode and a gate mask buried entirely in the recessed region.

In example embodiments, forming the gate structure may include forming a gate electrode and a gate mask buried entirely in the recessed region.

In example embodiments, the manufacturing process may include fewer photo processing operations. In example embodiments, the manufacturing process may include one photo processing operation.

### BRIEF DESCRIPTION OF THE DRAWINGS

The above and other features and advantages of example embodiments will become more apparent by describing them in detailed with reference to the accompanying drawings.

FIG. 1 illustrates a FinFET or recessed gate structure in accordance with the conventional art.

FIG. 2 illustrates a FinFET in accordance with example embodiments.

FIGS. 3A-3C, 4A-4C, 5A-5C, 6A-6C, 7A-7D, 8A-8D, 9A-9C, 10A-10C, 11A-11C, and 12A-12C illustrate a method of manufacturing a FinFET in example embodiments.

FIGS. 13 and 14 illustrate multiple buried gate structures formed in accordance with the process illustrated in FIGS. 3A-12C.

FIG. 15 illustrates a dynamic random access memory (DRAM) cell using a buried gate in accordance with example embodiments.

FIGS. 16-19 illustrate a method of forming the DRAM of FIG. 15, in accordance with example embodiments.

FIG. 20 illustrates a DRAM cell structure without contact plugs, in accordance with example embodiments.

FIGS. 21-24 illustrate a method of forming the DRAM of FIG. 20, in accordance with example embodiments.

### DETAILED DESCRIPTION

Detailed example embodiments are disclosed herein. However, specific structural and/or functional details disclosed herein are merely representative for purposes of describing example embodiments. The claims may, however, may be embodied in many alternate forms and should not be construed as limited to only example embodiments set forth herein.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and/or scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout. Example embodiments should not be construed as limited to the particular shapes of regions illustrated in these figures but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the claims.

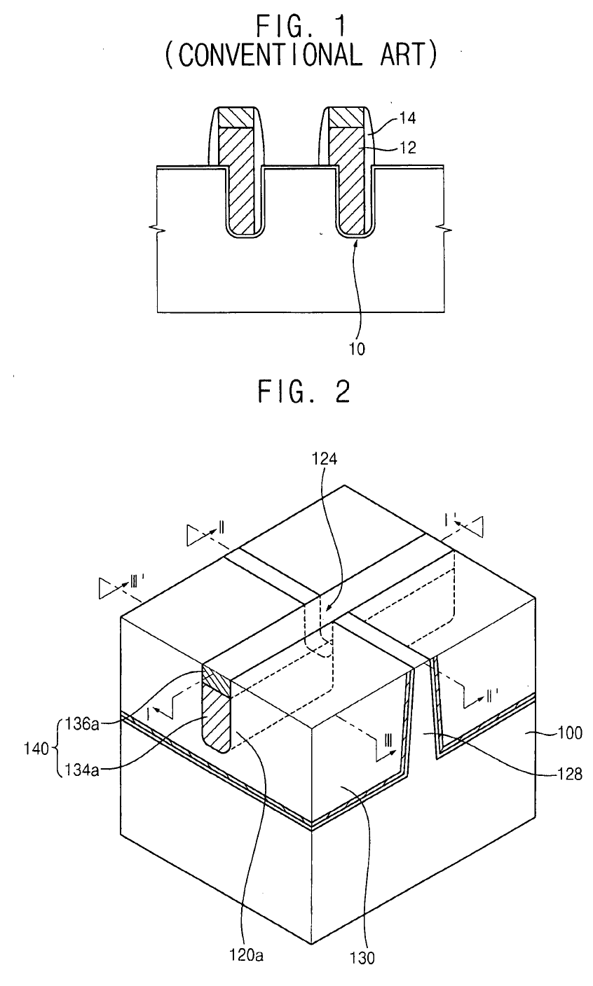

FIG. 2 illustrates a FinFET in accordance with example embodiments. As illustrated, the FinFET may include a substrate 100, a first trench 124, a second trench 120a, an active fin 128, an isolation layer 130, and a gate structure 140. The gate structure 140 may include a gate electrode 134a and/or a gate hard mask 136a. As illustrated, the gate structure 140 may be formed as a buried gate node FinFET structure 140 in the active fin 128 and the isolation layer 130.

As illustrated, the active fin 128 may be formed on or from the substrate 100. The active fin height 128 may be higher than a bottom surface of the isolation layer 130. As a result, both sides of the active fin 128 may be exposed and look like a fin. In example embodiments, the upper surface of the active fin 128 may be substantially planar with the upper surface of the isolation region 130. In example embodiments, an upper surface of the active fin 128 may be substantially planar with an upper surface of the isolation region 130 and a first portion of the upper surface of the isolation region 130 may be substantially planar with an upper surface of the active fin 128 and a second portion of the upper surface of the isolation region 130 adjacent to the active fin 128 may be lower than the upper surface of the active fin 128.

The active fin 128 may have a rounded or semicircular trench surface in a center area thereof, for example, the first trench 124 may have a rounded or semicircular trench surface in a center area thereof. Each portion of the active fin 128 on either side of the first trench 124 may be doped to act as a source or drain. In example embodiments, the recessed region increases a surface area overlap between the gate structure 140 and the active fin 128.

The gate structure 140 may be formed in the second trench 120a and the isolation layer 130 as a buried gate structure, by a chemical mechanical polishing (CMP) process. As a result, misalignment will not occur.

As shown in FIG. 2, the buried gate structure 140 may be substantially perpendicular to the active fin 128. As shown in FIG. 2, the buried gate structure 140 may overlap the active fin 128 in a recessed region in the center area between the source and the drain. As shown in FIG. 2, the gate electrode 134a may be buried entirely below an upper surface of the active fin 128 and/or an upper surface of the isolation region 130. As shown in FIG. 2, the buried gate structure 140 may be buried entirely below an upper surface of the active fin 128 and/or an upper surface of the isolation region 130.

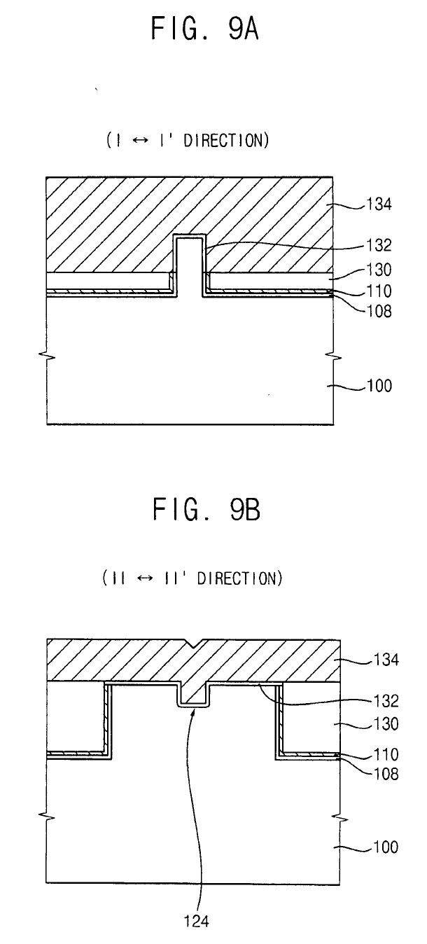

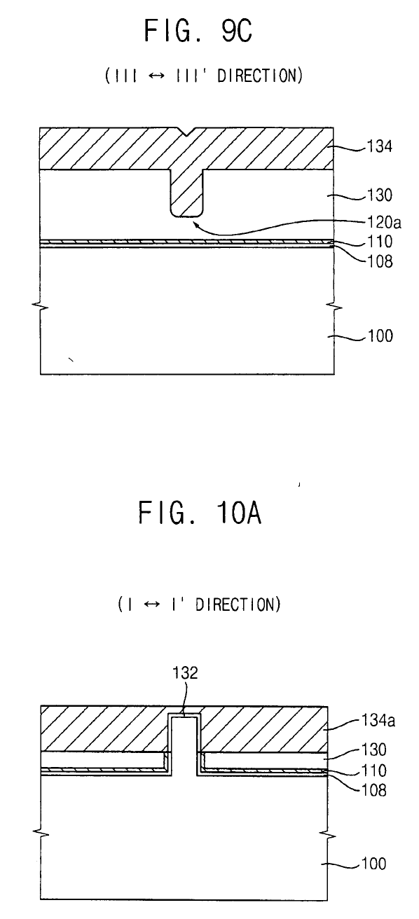

The buried gate structure 140 may further include a buried gate spacer (discussed in more detail below with respect to FIGS. 9A-12C and FIGS. 15 and 18-26) on sidewalls of the buried gate electrode 140. In example embodiments, the buried gate spacer may be buried entirely below the upper surface of the active fin 128 and the upper surface of the isolation region 130. In example embodiments, the buried gate spacer may be as wide as the active fin 128.

In other example embodiments, a portion of the buried gate structure 140 in the isolation region 130 may have a first depth and a portion of the buried gate structure 140 in the recessed portion may have a second depth, the first depth being greater than the second depth.

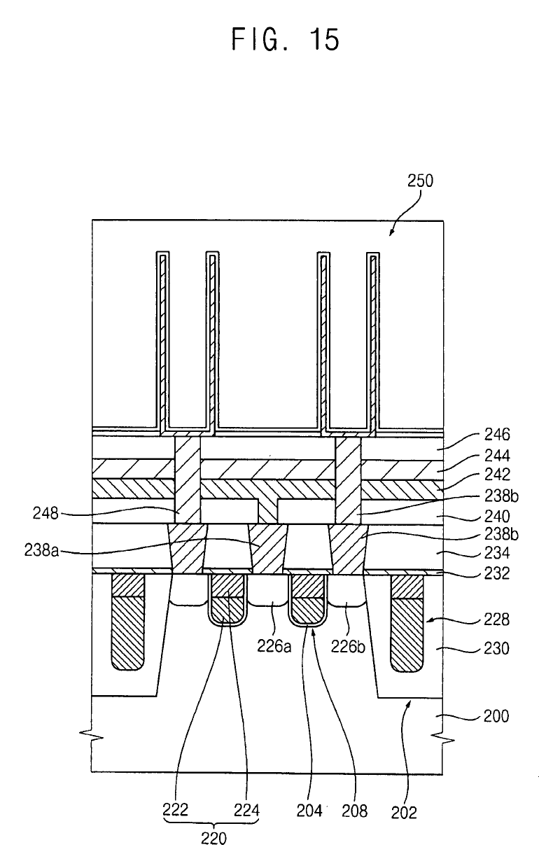

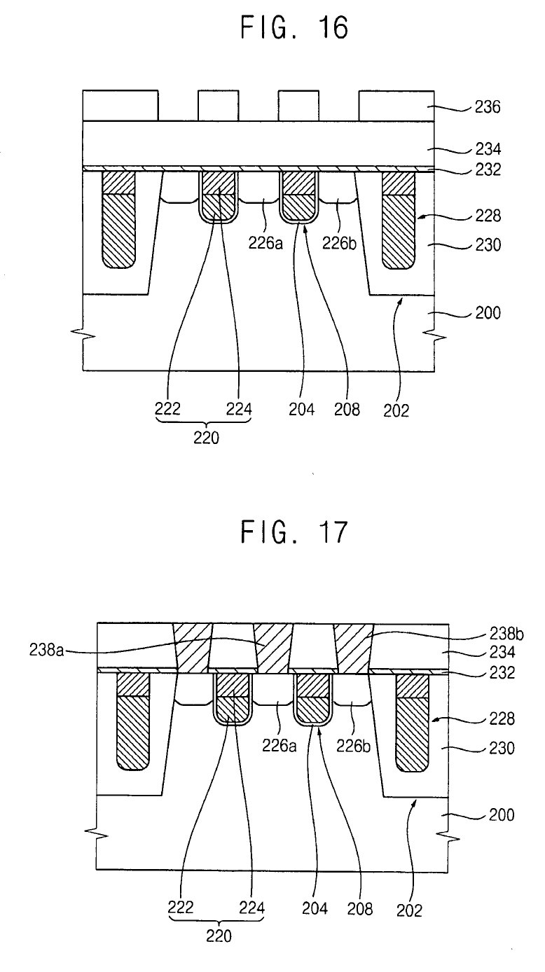

In example embodiments, the FET may further include a gate insulation layer on the active fin 128. An example of a gate insulation layer is a gate insulation layer 132 discussed below in conjunction with FIGS. 9A-12C and gate insulation layer 204, discussed below in conjunction with FIGS. 15 and 18-26.

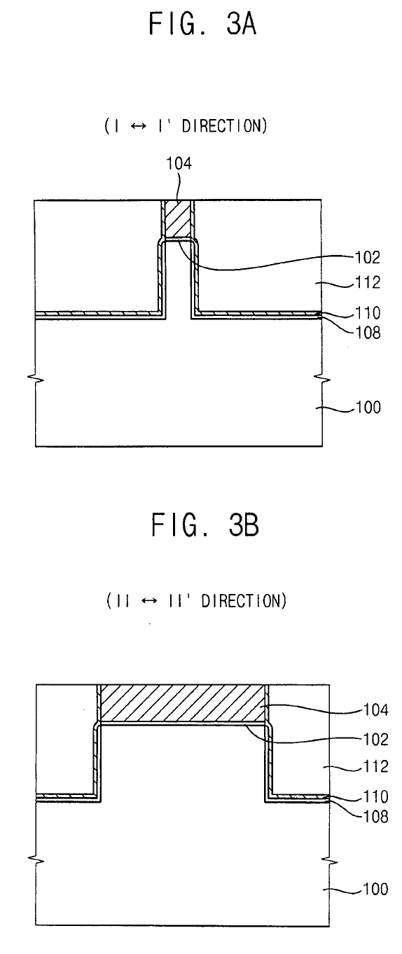

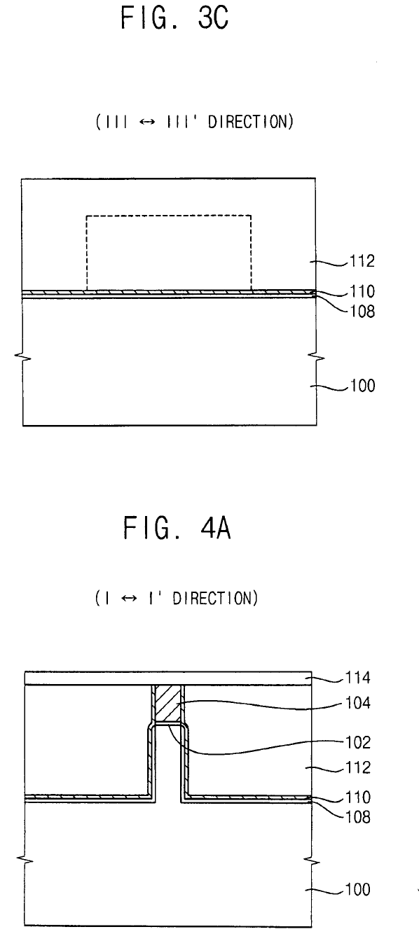

In example embodiments, the FET may further include an oxide layer between the substrate and the active fin and the isolation region and a nitride layer between the oxide layer and the isolation region. Examples of an oxide and a nitride layer are inner oxide 108 and nitride layer 110, discussed below in conjunction with FIGS. 3A-14.

In example embodiments, the FET may be included a part of a nonvolatile memory device, for example, a DRAM, with or without contact plugs, as discussed in more detail below with respect to FIGS. 15 and 22, respectively.

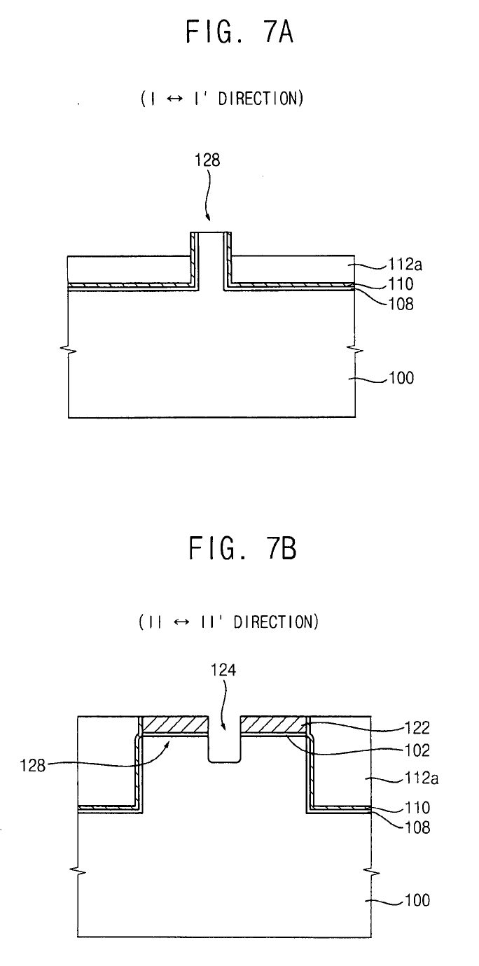

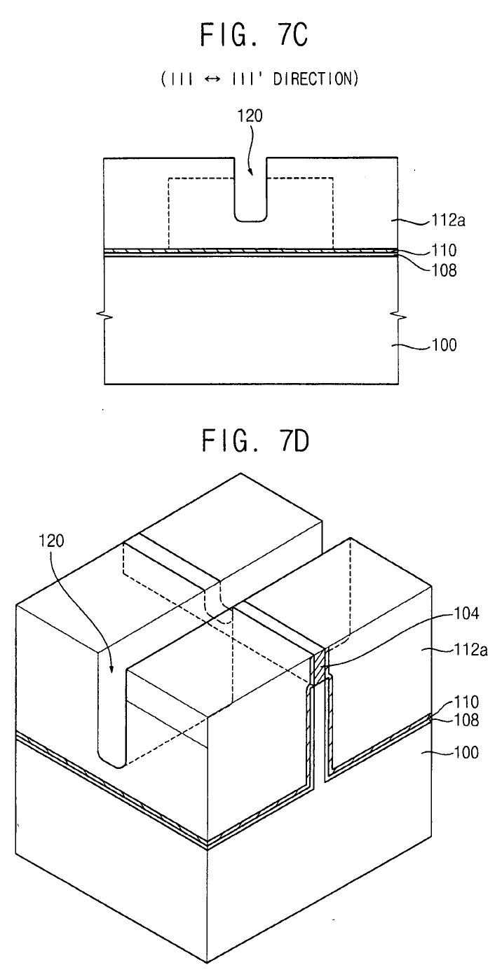

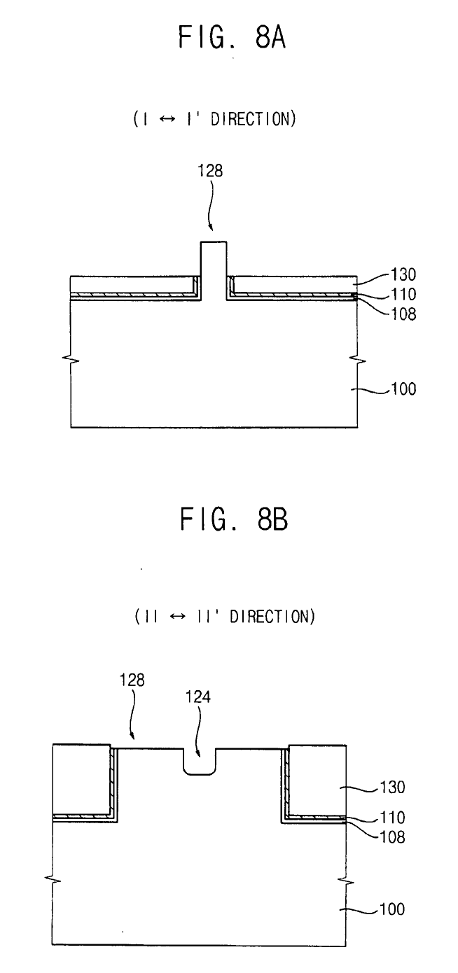

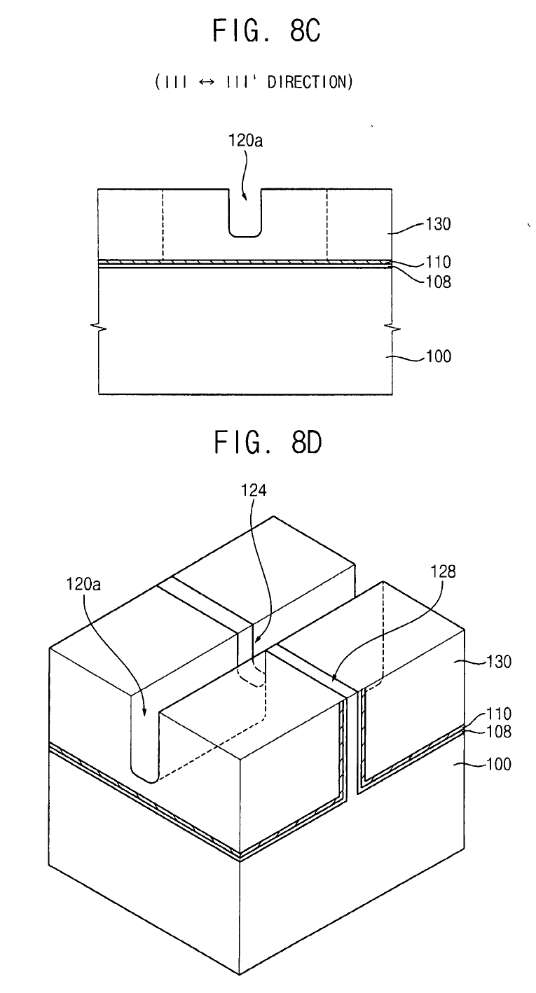

FIGS. 3A-3C to FIGS. 12A-12C illustrate a method of manufacturing the FinFET of FIG. 2 in example embodiments. FIGS. 3A, 4A, 5A, 6A, 7A, 8A, 9A, 10A, 11A, and 12A illustrate the example FinFET of FIG. 2 along line I-I′. FIGS. 3B, 4B, 5B, 6B, 7B, 8B, 9B, 10B, 11B, and 12B illustrate the example FinFET of FIG. 2 along line II-II′. FIGS. 3C, 4C, 5C, 6C, 7C, 8C, 9C, 10C, 11C, and 12C illustrate the example FinFET of FIG. 2 along line III-III′. FIGS. 7D and 8D illustrate perspective views of the example FinFET of FIG. 2.

As illustrated in FIGS. 3A-3C, the substrate 100 may be formed to have an active fin region and shallow trench isolation (STI) regions on either side. The active fin 128 may be formed in the active fin region by an STI process. As shown, the substrate 100 may be partly etched using a first hard mask 104. The first hard mask 104 may be formed by chemical vapor deposition (CVD). An inner oxide 108 may be formed on the partly etched region and a nitride layer 110 may be formed on the inner oxide 108. An isolation layer 112 may be formed on the nitride layer 110. A pad oxide 102 may be formed on the active fin 128 before the first hard mask 104 is formed. FIG. 3b illustrates the active fin region 128a and shallow trench isolation (STI) regions 112a, on either side. The STI regions 112a may be doped to form a source and drain, as described in more detail below.

Chemical vapor deposition (CVD) is a chemical process used to produce high-purity, high-performance solid materials. In a typical CVD process, a substrate such as a semiconductor wafer, is exposed to one or more volatile precursor compounds within a reaction chamber under a combination of pressure and radio frequency (RF) power sufficient to induce reaction and/or deposition of the precursor compounds on the substrate surface to produce the desired deposition layer. Parameters controlled during a CVD process may include, for example, pressure, RF power, substrate bias, substrate temperature and precursor compound feed rates. Unreacted precursor compounds and/or volatile byproducts are typically removed from the reaction chamber by a flow of carrier gas and/or pumping.

CVD processes may be broadly classified according to their operating pressure and include, for example, atmospheric pressure CVD (APCVD), low-pressure CVD (LPCVD), or ultrahigh vacuum CVD (UHVCVD) (a term generally applies to processes at pressures, typically below 10⁻⁶ Pa (˜10⁻⁸ torr), or by certain other characteristics including, for example, aerosol assisted CVD (AACVD), direct liquid injection CVD (DLICVD), microwave plasma-assisted CVD (MPCVD), plasma-enhanced CVD (PECVD), remote plasma-enhanced CVD (RPECVD), atomic layer CVD (ALCVD), hot wire CVD (HWCVD) (also known as catalytic CVD (Cat-CVD) or hot filament CVD (HFCVD), metalorganic chemical vapor deposition (MOCVD), rapid thermal CVD (RTCVD) and vapor phase epitaxy (VPE).

Silicon, for example, may be deposited using CVD processes that utilize the decomposition of silane (SiH₄), using a silane feedstock that may include nitrogen or other carrier gas(es). The silicon may also be doped by including an additional precursor compound, for example, phosphine, arsine and/or diborane during the deposition may be to the CVD chamber. Diborane increases the growth rate, but arsine and phosphine decrease growth rate.

Silicon dioxide is also commonly deposited using CVD processes using as feed gases a combination of silane, oxygen, dichlorosilane (SiCl₂H₂), nitrous oxide (N₂O), and/or tetraethylorthosilicate (TEOS; Si(OC₂H₅)₄). The choice of source gas(es) may be influenced by the thermal stability of the material(s) already present on the substrate. For example, silane can be used for forming oxide deposits between about 300 and 500° C., dichlorosilane at around 900° C., and TEOS between about 650 and 750° C. The choice of source gas(es) may also be influenced by the device requirements in that silane-based oxide depositions tend to exhibit reduced dielectric strength and tend to be less conformal than those achieved with dichlorosilane and/or TEOS. Like silicon, additional atomic species may be introduced into the silicon oxide during deposition to provide for alloyed and/or doped material layers including, for example, silicon dioxide alloyed with phosphorus pentoxide (P-glass) to permit reflow processing at temperatures above about 1000° C.

Although some metals, for example, aluminum and copper, are rarely deposited using a CVD process, other metals, particularly the refractory metals are commonly deposited using CVD processes including, for example, molybdenum, tantalum, titanium and tungsten and their oxides and nitrides.

While conventional device isolation technology for electrically isolating individual devices or active regions on which such devices will be formed during fabrication of semiconductor devices utilized local oxidation of silicon (LOCOS) method, increasingly demanding design rules have led to the widespread adoption of shallow trench isolation (STI) methods.

STI methods form device isolation regions by etching a pattern of shallow trenches into a substrate and then filling these trenches with one or more suitable dielectric materials, for example, silicon oxide. A typical STI method includes forming a hard pattern on the substrate, for example, the combination of a pad oxide layer and a nitride layer. This hard pattern is then used as an etch mask for removing a portion of the exposed substrate to form a trench pattern. An insulating material may then be applied to the etched substrate to fill the trench pattern and the resulting structure may be subjected to chemical mechanical polishing (CMP) and/or etchback processes to expose the active regions under the hard mask and provide a planar surface suitable for subsequent processing. An optional capping layer may also be applied to the primary insulating material.

The insulating material(s) may be applied using a variety of techniques including, for example, chemical vapor deposition (CVD) and/or spin-on-glass (SOG) methods and may include materials such as high density plasma CVD (HDP-CVD) oxides, undoped silicate glasses (USG), doped silicate glasses (PSG, BSG, BPSG) and/or tetraethylorthosilicate (TEOS) oxides.

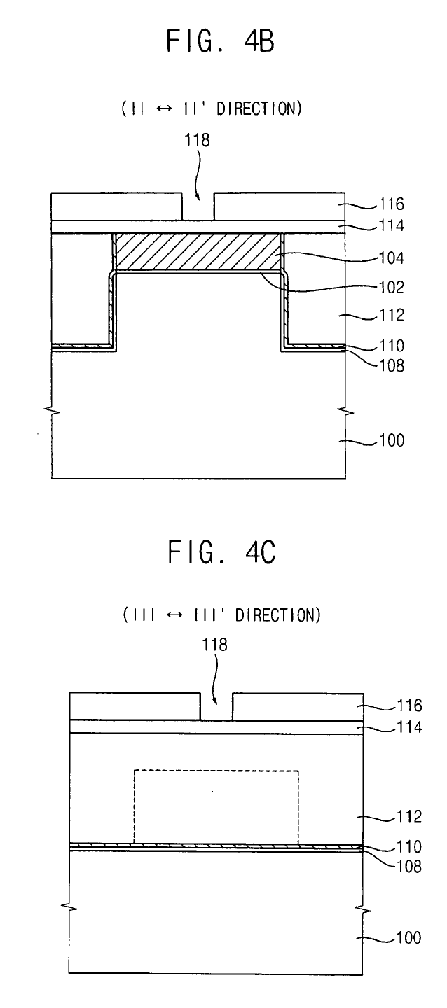

As illustrated in FIGS. 4A-4C, an anti-reflection layer 114 and a thermal resist layer 116 may be formed on the active fin 128 and the isolation layer 112. A hole 118 may be formed on the active fin 128 across or perpendicular to the active fin direction.

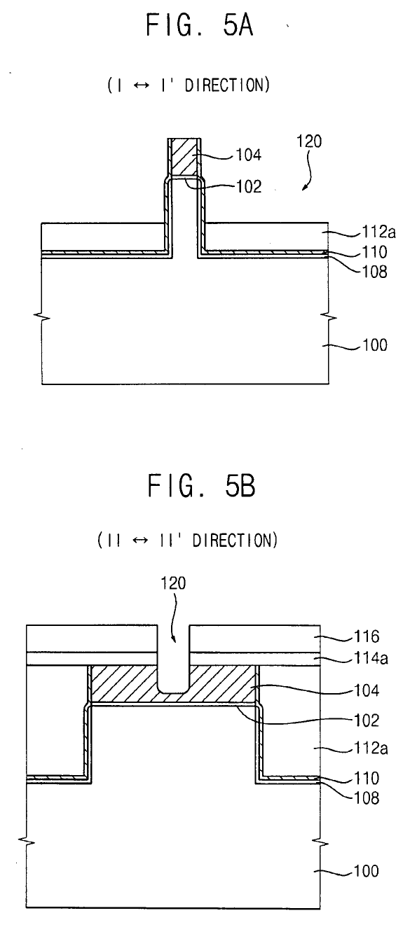

As illustrated in FIGS. 5A-5C, a second trench 120 may be formed on the isolation layer 112 and the first hard mask layer 104. The second trench 120 may be substantially perpendicular to the active fin 128 and intersect the active fin 128 in the recessed region in the center area between the source and the drain and buried entirely below an upper surface of the active fin 128 and an upper surface of the isolation layer 112.

A depth of the second trench 120 may vary. For example, as shown in FIG. 2, the depth of the second trench 120 may be shallower at the intersection with the active fin 128, which may also define the first trench 124. A depth of the second trench 120 may be less than a height of the active fin 128. The second trench 120 may be filled with the gate structure 140, discussed above in conjunction with FIG. 2.

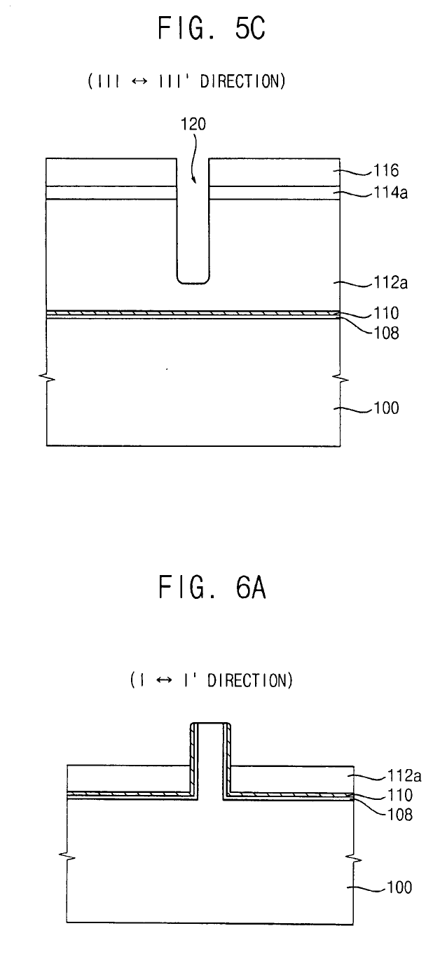

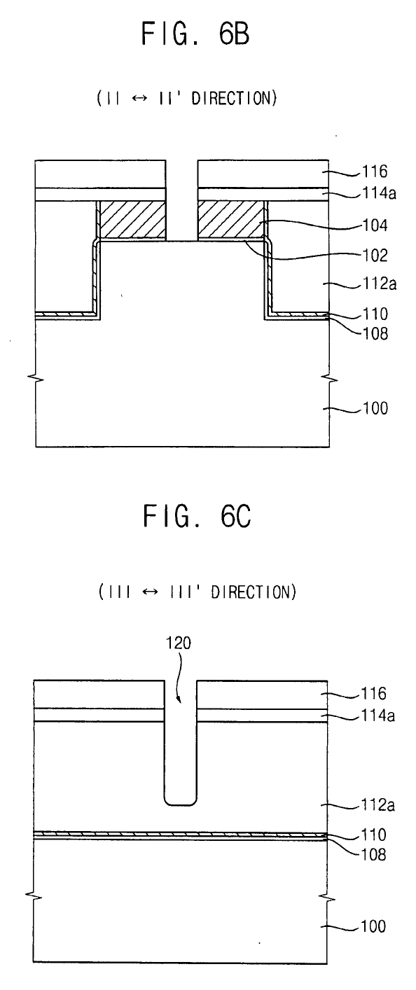

As illustrated in FIG. 6A-6C, the first hard mask layer 104 may be etched away along line I-I′, by a selective etch process, but remain along lines II-II′ and III-III′, as shown in FIGS. 6B and 6C, respectively.

As illustrated in FIGS. 7A-7C, the anti-reflection layer 114 and the first photo resist layer 116 may be removed by an etching process. Also, a portion of the first hard mask layer 104 may be etched away along line II-II′, by a selective etch process, as shown in FIG. 7B, to form a second hard mask layer 122. The result of the above processes may be that the first trench 124 is formed in the active fin 128. As discussed above, a depth of the first trench 124 may be less than a depth of the second trench 120. FIG. 7D illustrates a perspective view of an example FinFET at this point in processing.

As illustrated in FIGS. 8A-8C, the second hard mask layer 122 and the pad oxide 102 may be removed by a wet etch process. FIG. 8D illustrates a perspective view of an example FinFET at this point in processing.

As illustrated in FIGS. 9A-9C, a gate insulation layer 132 may be formed on the active fin 128. The gate insulation layer 132 may include an oxide layer, a nitride layer, an aluminum oxide layer, and/or a high dielectric layer.

The gate insulation layer 132 may act as a buried gate spacer on sidewalls of the active fin 128. In example embodiments, the buried gate spacer may be buried entirely below the upper surface of the active fin 128 and the upper surface of the isolation region 130. In example embodiments, the buried gate spacer may be as wide as the active fin 128.

A gate electrode 134 may be formed in the first trench 124 between source and drain regions, in the second trench 120, on the gate insulation layer 132, and/or on the isolation layer 130.

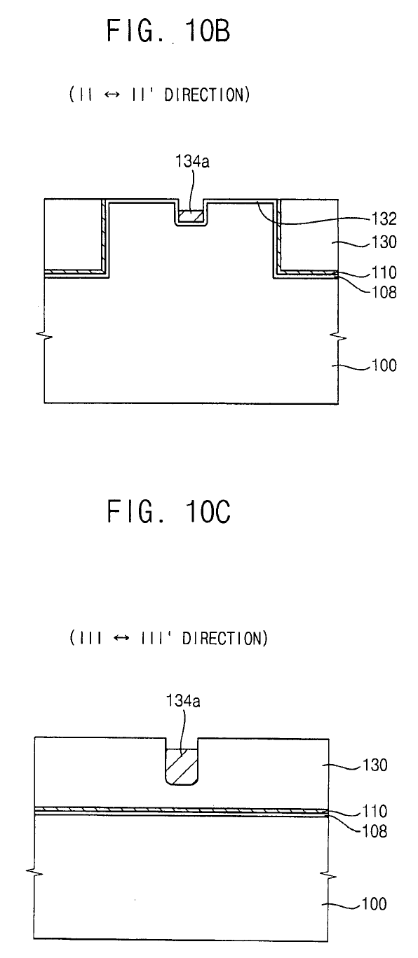

As illustrated in FIGS. 10A-10C, the gate electrode 134 may be partly removed by etching (wet or dry) and a CMP process. The gate electrode 134 may remain in the first trench 124 and the second trench 120. An upper surface of the gate electrode 134 may be planar with or below an upper surface of the isolation layer 130.

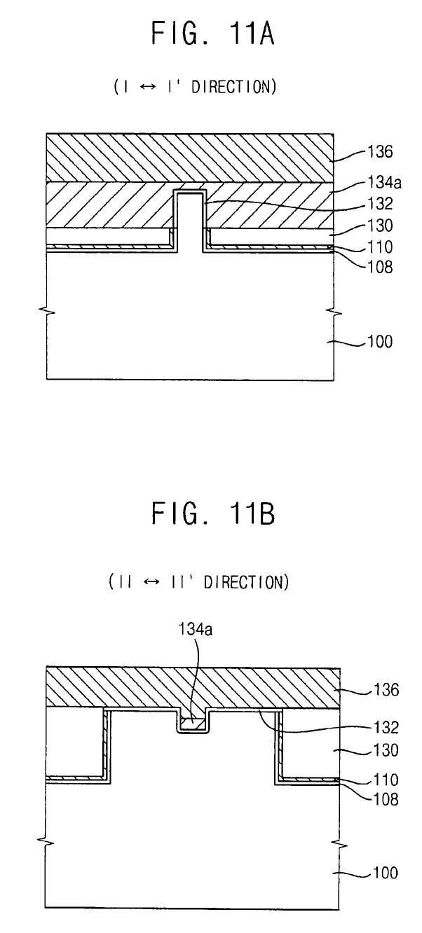

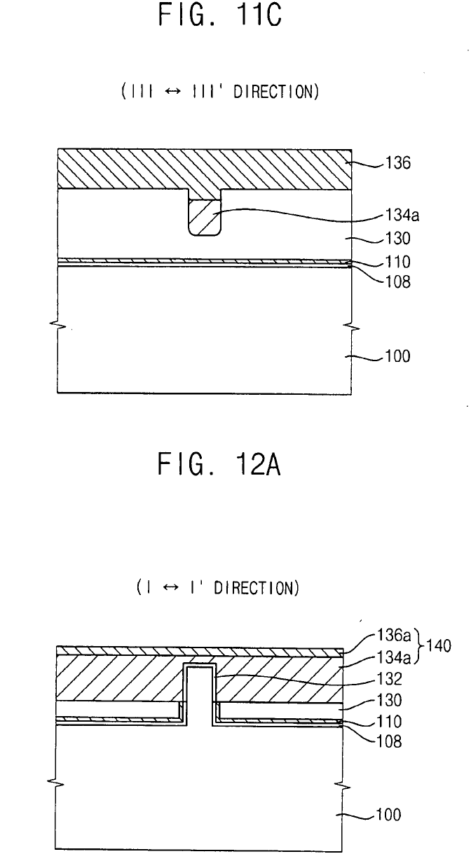

As illustrated in FIGS. 11A-11C, the gate mask layer 136 may be formed on the gate electrode 134. If the upper surface of the gate electrode 134 is below the upper surface of the isolation layer 130, the gate mask layer 136 may occupy that space.

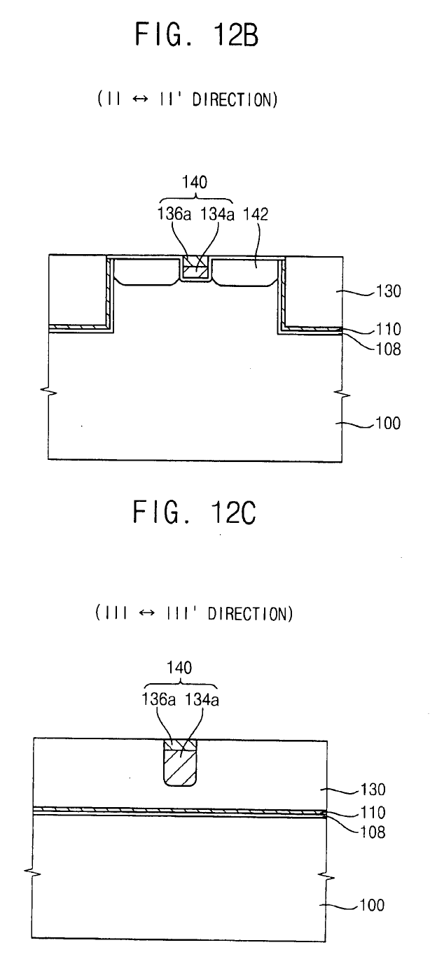

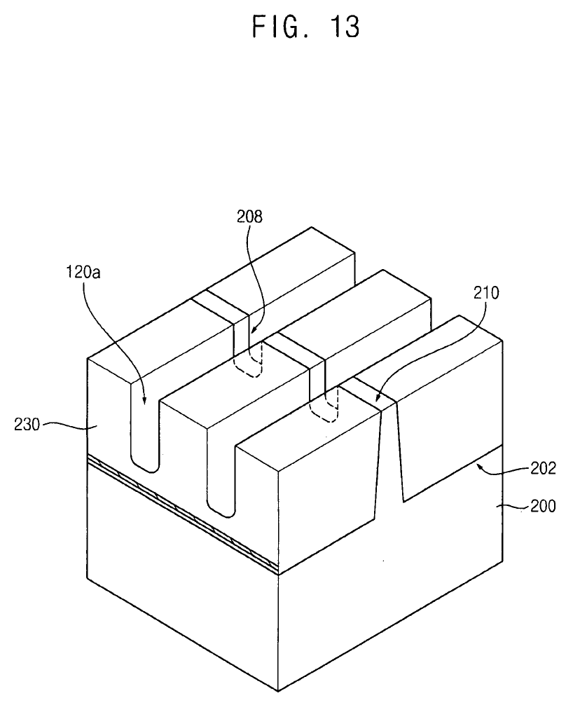

As illustrated in FIGS. 12A-12C, the gate mask layer 136 may be partly removed by a CMP process. As described above, the gate structure 140 may be formed by a damascene process therefore, no misalignment of the gate structure 140 may occur. As described above, source and drain regions 142 may be formed by an ion implantation process (IIP) in the active fin 128.

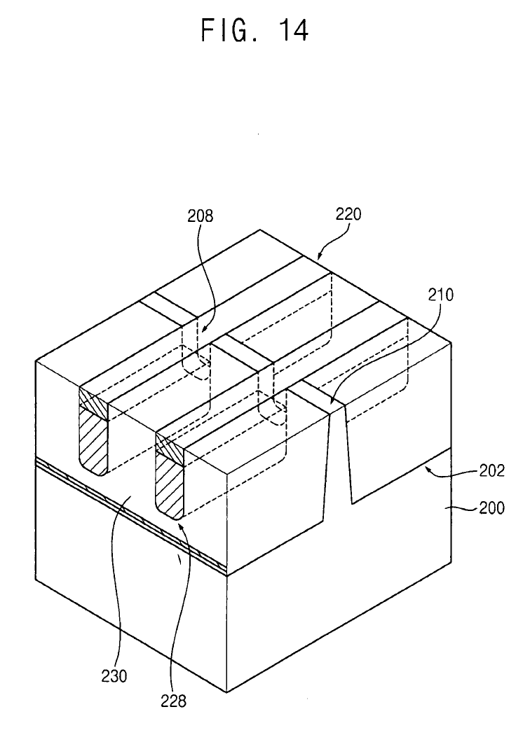

FIGS. 13 and 14 illustrate two buried gate structures formed in accordance with the process illustrated in FIGS. 3A-12C. As illustrated in FIGS. 13 and 14, the FinFET may include a substrate 200, an isolation trench 202, a first trench 208, an active fin 210, an isolation layer 230, a gate structure 220, and/or a second trench 228.

FIG. 15 illustrates a dynamic random access memory (DRAM) cell using a buried gate in accordance with example embodiments. As illustrated in FIG. 15, the DRAM cell may include substrate 200, an STI region 202, a gate insulation layer 204, a first trench 208, a gate structure 220, source and drain regions 226a, 226b, an isolation layer 230, an etch stopper 232, a first inner layer dielectric (ILD) 234, contact plugs 238a, a second ILD 240, a bit line 242, a hard mask 244, a third ILD 246, storage node contacts 238b, and/or a storage node, for example, capacitor 250.

As shown in FIG. 15, some of the contact plugs 238a may act as a bit line contact to connect the source region 226a to the bit line 242. The storage node contacts 238b may act as a storage node contact to connect the drain region 226b to the capacitor 250.

The gate insulation layer 204 may act as a buried gate spacer on sidewalls of the active fin 128. In example embodiments, the buried gate spacer may be buried entirely below the upper surface of the active fin 128 and the upper surface of the isolation region 230. In example embodiments, the buried gate spacer may be as wide as the active fin 128.

FIGS. 16-19 illustrate a method of forming the DRAM of FIG. 15, in accordance with example embodiments. As illustrated in FIG. 16, an etch stop layer 232 may be formed on the substrate 200. A first ILD layer 234 may be formed on the etch stop layer 232 by a CVD process. A contact plug hole may be formed in the first ILD layer 234, using a photo resist pattern 236, by an etching process. A contact plug 238a may be formed in the contact hole by a CVD and CMP process.

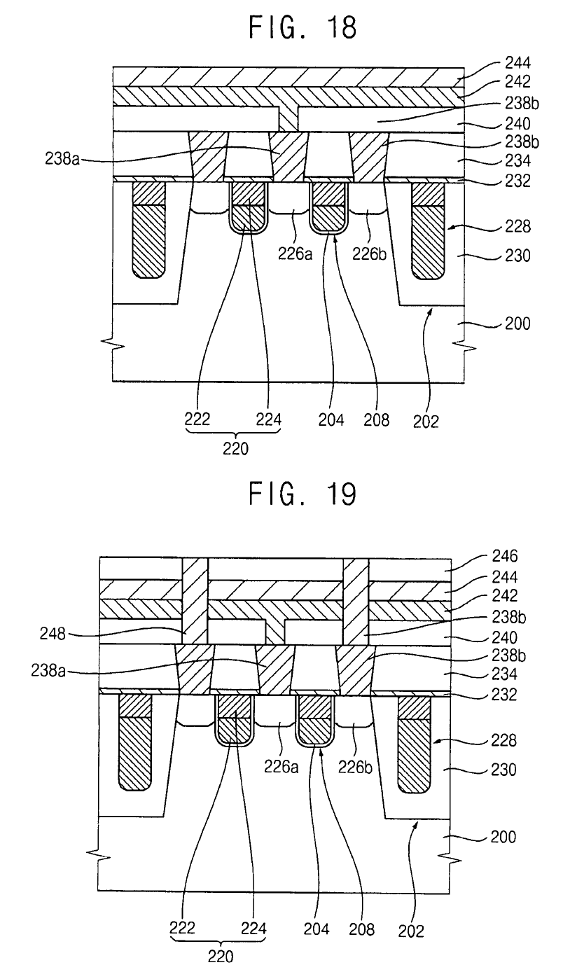

As illustrated in FIGS. 18 and 19, a second ILD layer 240 may be formed on the first ILD layer 234. A contact plug hole may be formed in the second ILD layer 240, using a photo resist pattern (not shown), by an etching process. A bit line 242 may be formed on the second ILD layer 240 and in the contact plug hole. A second hard mask layer 244 may be formed on the bit line 242. A third ILD layer 246 and a storage node, for example, capacitor 250 may be formed by a conventional CVD, photo, etch, and CMP process.

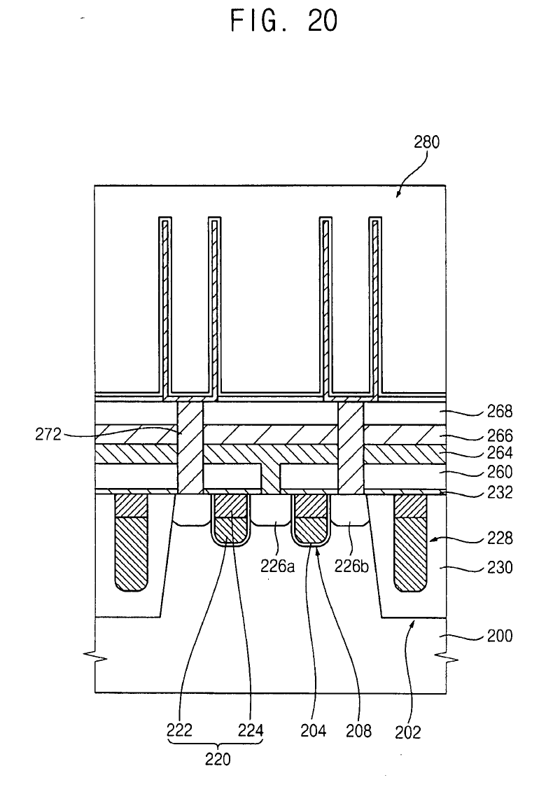

FIG. 20 illustrates a DRAM cell structure without contact plugs, in accordance with example embodiments. As illustrated in FIG. 20, the DRAM cell structure may include a first ILD 260, a bit line 264, a hard mask 266, a second ILD 268, a storage node contact 272, and a capacitor structure 280.

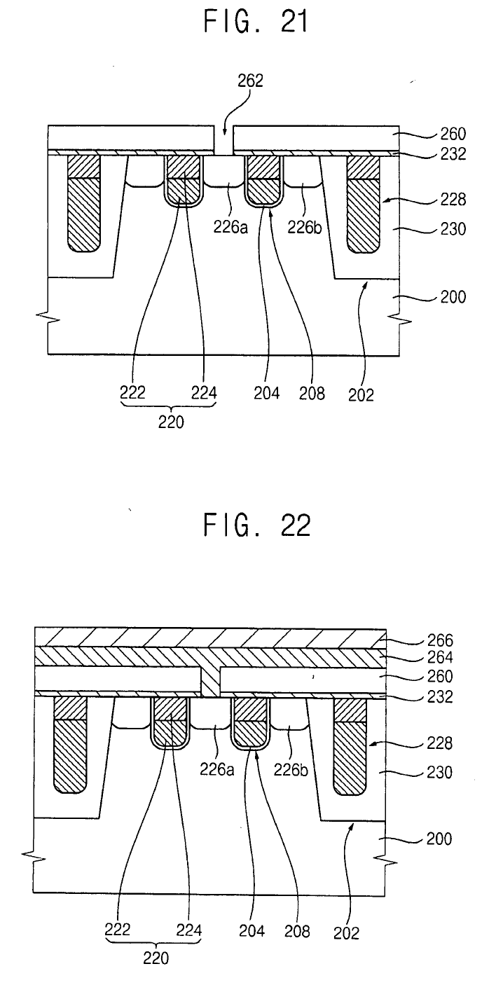

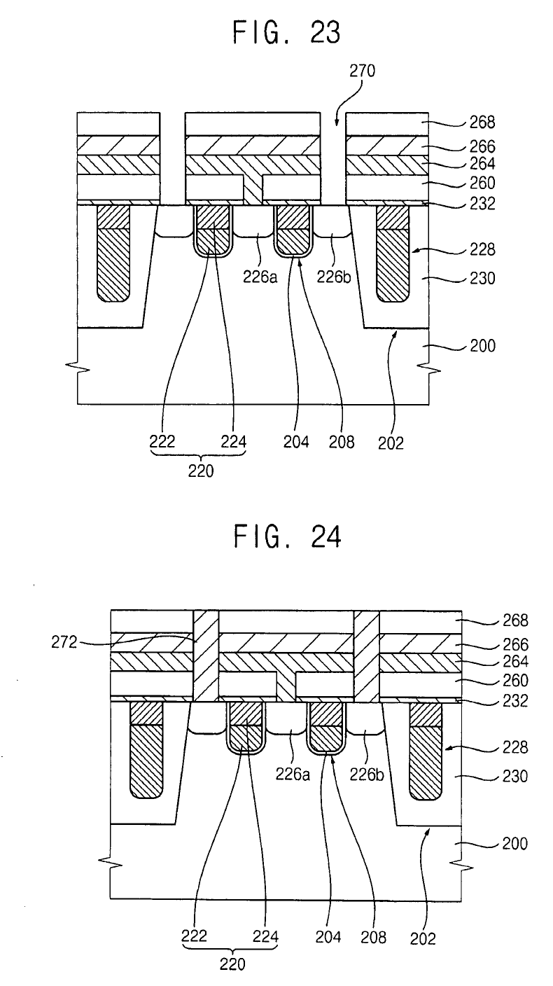

As illustrated in FIGS. 21 and 22, the first ILD layer 260 may be formed on the etch stop layer 232 by a CVD process and a bit line hole 262 may be formed in the first ILD layer 260. A bit line 264 and hard mask 266 may be formed on the first ILD layer 260. As illustrated in FIGS. 23 and 24, a second ILD layer 268 may be formed on the hard mask layer 266 by a CVD process. A storage contact hole 270 may be formed between the STI regions and the cell gate regions by a photo and etch process. A storage node contact 272 may be formed in the storage node contact hole 270 by a CVD and CMP process.

As described above, example embodiments may increase the length of the channel for a similar sized conventional FET. As a result, the “short channel effect” may be reduced.

As described above, example embodiments may increase the width of the channel for a similar sized conventional FET. As a result, the “narrow width effect” may be reduced.

As described above, example embodiments may reduce or prevent an increase in the threshold.

Any of the above features may be used to improve or maximize device performance, and/or reduce the sizes of elements formed on a substrate.

As described above, example embodiments may use a damascene process to reduce or prevent a misaligned gate node and/or to simplify the FET manufacturing process.

Although example embodiments have been described above, these example embodiments may be varied and/or augmented in many ways.

For example, although example embodiments as illustrated in FIGS. 2, 7d, 8d, 13-15, and 20 illustrate a curved, rounded or semicircular surface for trenches 120a and 124, either or both of these trenches may have any other shape which increases the channel length and/or width, including, but not limited to rectangular, sloped, triangular, etc.

Further, example embodiments, as described above, may be implemented in any number of field effect transistors, for example, metal-oxide-semiconductor FETs (MOSFETs), junction FETs (JFETs), metal semiconductor FETs (MESFETs), heterostructure FETs (HFETs), and/or modulation-doped FETs (MODFETs).

Example embodiments, as described above, may also be used in many types of non-volatile semiconductor memory, for example, floating gate non-volatile memory, nitride non-volatile memory, ferroelectric memories, magnetic memories, and/or phase change memories.

Example embodiments, as described above, may include any type of charge storing device, for example, a floating gate storage charge storage device, a charge trap layer storage device, and/or a nanocrystalline charge storing device.

Example embodiments, as described above, may also be used in many types of memory cells, for example, a metal-oxide-insulator-oxide-semiconductor (MOIOS), for example, a silicon-oxide-nitride-oxide-semiconductor (SONOS), a metal-oxide-nitride-oxide-semiconductor (MONOS), or a tantalum-aluminum oxide-nitride-oxide-semiconductor (TANOS). As set forth above, a SONOS structure may use silicon as the control gate material, a MONOS structure may use a metal as the control gate material, and a TANOS structure may use tantalum as the control gate material.

An MOIOS memory device may also use a charge trap layer, for example, silicon-nitride (Si₃N₄) instead of a floating gate as a charge storing device. The MOIOS memory device may have another structure in which nitride and oxide may be sequentially stacked instead of a stacked structure formed of a floating gate and insulating layer stacked on the upper and lower portions between the substrate and the control gate as in the memory cell of a flash semiconductor device. The MOIOS memory device may use the shifting characteristic of the threshold voltage as charges may be trapped in the insulator or nitride layer.

Although example embodiments illustrated in FIG. 2 include one gate structure and example embodiments illustrated in FIGS. 13-14 include two gate structures, any number of gate structures may be provided, as needed.

Example embodiments, as described above, may be implemented in flash memory, for example, NOT-OR (NOR) type and NOT-AND (NAND) flash memory. Example embodiments, as set forth above, may be arranged in a circuit array, for example, in an array of NOR or NAND strings.

Example embodiments, as described above, may also be stacked on another similar arrangement, separated by an insulator, for example, a dielectric. The stack may be a vertical stack and may include two or more arrangements as illustrated in FIGS. 2 and/or 13-14.

Example embodiments, as described above, may also be implemented in charge storage devices which store a single bit of data or in a multi-level cell, where two or more bits may be stored.

Example embodiments, as described above, may be implemented in non-volatile memory used in various electronic products, for example, personal computers, personal digital assistants (PDAs), cellular phones, digital still cameras, digital video cameras, video game players, memory cards, and other electronic devices. Example embodiments as described above may also be implemented in non-volatile memory cards including multimedia cards (MMC), secure digital (SD) cards, compact flash cards, memory sticks, smart media cards, and extreme digital (xD) picture cards.

While example embodiments have been particularly shown and described with reference to the example embodiments shown in the drawings, it will be understood by those of ordinary skill in the art that various changes in form and detail may be made therein without departing from the spirit and scope of the following claims.

What is claimed is:

1. A field effect transistor (FET), comprising:
an active fin formed from a substrate, the active fin surrounded by an isolation region and including a source and a drain, and a recessed region in a center area between the source and the drain; and
at least one buried gate structure, including a buried gate electrode and a buried gate mask,
the at least one buried gate structure substantially perpendicular to the active fin and overlapping the active fin in the recessed region in the center area between the source and the drain,
the at least one buried gate structure buried entirely below an upper surface of the active fin and an upper surface of the isolation region.

2. The field effect transistor (FET) of claim 1, wherein the upper surface of the active fin is substantially planar with the upper surface of the isolation region.

3. The field effect transistor (FET) of claim 1, wherein an upper surface of the active fin is substantially planar with an upper surface of the isolation region and a first portion of the upper surface of the isolation region is substantially planar with an upper surface of the active fin and a second portion of the upper surface of the isolation region adjacent to the active fin is lower than the upper surface of the active fin.

4. The field effect transistor (FET) of claim 1, wherein the at least one buried gate structure further includes a buried gate spacer on sidewalls of the buried gate electrode and wherein the buried gate spacer is buried entirely below the upper surface of the active fin and the upper surface of the isolation region.

5. The field effect transistor (FET) of claim 4, wherein the buried gate spacer is as wide as the active fin.

6. The field effect transistor (FET) of claim 1, wherein the buried gate structure in the isolation region has a first depth and the buried gate structure in the recessed portion has a second depth, the first depth greater than the second depth.

7. The field effect transistor (FET) of claim 1, further comprising:
a gate insulation layer on the active fin.

8. The field effect transistor (FET) of claim 1, further comprising:
an oxide layer between the substrate and the active fin and the isolation region and a nitride layer between the oxide layer and the isolation region.

9. The field effect transistor (FET) of claim 1, wherein a bottom surface of the recessed region has a semicircular shape.

10. The field effect transistor (FET) of claim 1, wherein the recessed region increases a surface area overlap between the at least one buried gate structure and the active fin.

11. A DRAM comprising:
the field effect transistor (FET) of claim 1;
a bit line contact, connecting the source to a bit line; and
a storage node contact, connecting the drain to a storage node.

12. A DRAM comprising:
the field effect transistor (FET) of claim 1;
a first contact plug, contacting the source;
a second contact plug, contacting the drain;
a bit line contact, connecting the first contact plug to a bit line; and
a storage node contact, connecting the second contact plug to a storage node.

13. A method of forming a field effect transistor (FET), comprising:
forming an active fin, including a source area and drain area, from a substrate and an isolation region surrounding the active fin;
forming a recessed region in a center area of the active fin; and
forming a buried gate structure, including a buried gate electrode and a buried gate mask, substantially perpendicular to the active fin and overlapping the active fin in the recessed region in the center area between the source and the drain and buried entirely below an upper surface of the active fin and an upper surface of the isolation region.

14. The method of claim 13, wherein the upper surface of the active fin is substantially planar with the upper surface of the isolation region and an upper surface of the buried gate mask.

15. The method of claim 13, wherein an upper surface of the active fin is substantially planar with an upper surface of the isolation region and a first portion of the upper surface of the isolation region is substantially planar with an upper surface of the active fin and a second portion of the upper surface of the isolation region adjacent to the active fin is lower than the upper surface of the active fin.

16. The method of claim 13, wherein the active fin and the isolation region are formed by shallow trench isolation (STI).

17. The method of claim 13, wherein forming the active fin further includes,
forming a pad oxide on the substrate,
forming a hard mask layer on the pad oxide by chemical vapor deposition (CVD); and
forming an isolation layer in the isolation region.

18. The method of claim 17, wherein forming the recessed region in the center area of the active fin further includes,
forming a trench in the hard mask layer and the isolation layer, where a depth of trench in the hard mask layer is shallower than a depth of the trench in the isolation layer,
removing a top portion of the hard mask layer, and
forming the recessed region in the active fin, where a depth of the recessed region in the active fin is shallower than a depth of the trench in the isolation layer, and

19. The method of claim 18, wherein forming the buried gate structure further includes,
forming a gate insulation layer on the active fin and in the recessed region of the active fin,
forming a gate electrode layer on the gate insulation layer on the active fin and in the recessed region of the active fin,
removing an entire portion of the gate electrode layer on the active fin and a top portion of the gate electrode layer in the recessed region of the active fin and a remaining portion of the gate electrode layer such that the remaining buried gate electrode is entirely below the upper surface of the active fin, and
forming a gate mask in the recessed region of the active fin.

20. The method of claim 19, wherein the gate insulation layer includes at least one of an oxide layer, a nitride layer, and a metal oxide layer.

21. The method of claim 19, wherein forming the buried gate structure further includes,
forming a buried gate spacer on sidewalls of the buried gate electrode,
wherein the buried gate spacer is entirely below the upper surface of the active fin and the upper surface of the isolation region.

22. The method of claim 13, further comprising:
forming a source and a drain in the source area and drain area, respectively, by ion implantation.

23. The method of claim 22, further comprising:
forming a bit line contact, connecting the source to a bit line; and
forming a storage node contact, connecting the drain to a storage node.

24. The method of claim 22, further comprising:
forming a first contact plug, contacting the source;
forming a second contact plug, contacting the drain;
forming a bit line contact, connecting the first contact plug to a bit line; and
forming a storage node contact, connecting the second contact plug to a storage node.

25. A method of forming a field effect transistor (FET), comprising:
forming an active fin and isolation layer on a substrate by shallow trench isolation;
forming a trench in a center area of the active fin and the isolation layer, where a depth of the trench in the active fin is shallower than a depth of the trench in the isolation layer;
forming a recessed region in the center area of the active fin;
depositing a gate insulation layer on an upper surface of the active fin and in the recessed region;
forming a gate structure buried entirely in the recessed region; and
forming a source and drain, at an upper portion of the active fin, elevated with respect to the gate structure.

26. The method of claim 25, wherein forming the gate structure includes forming a gate electrode and a gate mask buried entirely in the recessed region.

27. The method of claim 26, wherein forming the gate structure includes forming a gate electrode and a gate mask buried entirely in the recessed region.
